(19) United States
(12) Patent Application Publication
(10) Pub. No.: US 2026/0291143 A1
(43) Pub. Date: Sep. 24, 2026

(54) SHIELDED INTERCONNECT

(71) Applicant: INTERNATIONAL BUSINESS MACHINES CORPORATION, Armonk, NY (US)

(72) Inventors: Jacob Dixon, Rochester, MN (US); Phillip V. Mann, Rochester, MN (US); William James Anderl, Rochester, MN (US); Steven Chandler Borrillo, Rochester, MN (US)

(21) Appl. No.: 19/082,259

(22) Filed: Mar. 18, 2025

(51) Int. Cl. H01R 13/6592

(52) U.S. Cl. CPC H01R 13/6592

(57) ABSTRACT

An apparatus includes a plurality of conductive members and a first expandable band of a conductive sheath, wherein the plurality of conductive members are coupled to the first expandable band. The apparatus further includes a cable connector disposed in an aperture of the first expandable band of the conductive sheath, wherein the plurality of conductive members surround the cable connector along a perimeter of the first expandable band.

### BACKGROUND

This disclosure relates generally to electromagnetic compatibility (EMC) shielding, and in particular, to EMC shielding of interconnects.

Electromagnetic interference (EMI) is electromagnetic energy representing a disturbance that affects functionality of an electrical circuit. The disturbance can degrade performance of the electrical circuit, which can lead to an increase in an error rate or loss of data. Information technology (IT) equipment installed on a server rack are examples of EMI producing devices. Electromagnetic compatibility (EMC) is the ability of electrical equipment and systems to function in an environment by limiting the effects of EMI producing devices.

### SUMMARY

One aspect of an embodiment of the present invention discloses an apparatus for a conductive sheath for a cable connector, the apparatus comprising a plurality of conductive members and a first expandable band of the conductive sheath, where the plurality of conductive members are coupled to the first expandable band. The apparatus further comprising the cable connector disposed in an aperture of the first expandable band of the conductive sheath, wherein the plurality of conductive members surround the cable connector along a perimeter of the first expandable band.

Another aspect of an embodiment of the present invention discloses an apparatus for a cable connector with a deployable sheath, the apparatus comprising a fixed case, a plurality of flexible members, and a plurality of conductive members of the deployable sheath, wherein the plurality of flexible members are coupled to the fixed case. The apparatus further comprising the cable connector disposed in a void defined by the fixed case and the plurality of flexible members, wherein the plurality of conductive members are coupled to and surround the cable connector.

Another aspect of an embodiment of the present invention discloses an apparatus for a cable connector with conductive strips, the apparatus comprising a plurality of conductive members coupled to the cable connector disposed in a connector housing, wherein at least one of the plurality of conductive members is flared out against a wall and covers a gap between an enclosure of the connector housing and the wall.

### BRIEF DESCRIPTION OF THE SEVERAL VIEWS OF THE DRAWINGS

The following detailed description, given by way of example and not intended to limit the disclosure solely thereto, will best be appreciated in conjunction with the accompanying drawings, in which:

FIG. 1 depicts a top view of a conductive sheath for a cable connector to provide EMC shielding surrounding a connector housing, in accordance with an embodiment of the present invention.

FIG. 2 depicts a cross-sectional view of an elastic band of a conductive sheath for a cable connector, in accordance with an embodiment of the present invention.

FIG. 3 depicts a cross-sectional view of an elastic band of a conductive sheath for a cable connector in an expanded state, in accordance with an embodiment of the present invention.

FIG. 4 depicts a top view of a conductive sheath prior to insertion of a cable connector to provide EMC shielding surrounding a connector housing, in accordance with an embodiment of the present invention.

FIG. 5 depicts a top view of a conductive sheath with a partially inserted cable connector to provide EMC shielding surrounding a connector housing, in accordance with an embodiment of the present invention.

FIG. 6 depicts a top view of a conductive sheath with an inserted cable connector prior to insertion into a connector housing, in accordance with an embodiment of the present invention.

FIG. 7 depicts a top view of a conductive sheath with an inserted cable connector inserted into a connector housing to provide EMC shielding surrounding the connector housing, in accordance with an embodiment of the present invention.

FIG. 8 depicts a side view of a cable connector with a deployable sheath prior to insertion into a connector housing, in accordance with an embodiment of the present invention.

FIG. 9 depicts a side view of a cable connector with a deployable sheath inserted into a connector housing, in accordance with an embodiment of the present invention.

FIG. 10 depicts a side view of a cable connector with a deployable sheath inserted into a connector housing, in accordance with an embodiment of the present invention.

FIG. 11 depicts a side view of a cable connector with conductive strips prior to insertion into a connector housing, in accordance with an embodiment of the present invention.

FIG. 12 depicts a side view of a cable connector with conductive strips partially inserted into a connector housing, in accordance with an embodiment of the present invention.

FIG. 13 depicts a side view of a cable connector with conductive strips inserted into a connector housing, in accordance with an embodiment of the present invention.

FIG. 14 depicts a process flow selecting and deploying an EMC shield for a connector housing, in accordance with an embodiment of the present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

Detailed embodiments of the present invention are disclosed herein with reference to the accompanying drawings; however, it is to be understood that the disclosed embodiments are merely illustrative of potential embodiments of the invention and may take various forms. In addition, each of the examples given in connection with the various embodiments is also intended to be illustrative, and not restrictive. This description is intended to be interpreted merely as a representative basis for teaching one skilled in the art to variously employ the various aspects of the present disclosure. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements. The term substantially, or substantially similar, refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labeling for the same or similar elements in some drawings may be omitted as well in order not to overcrowd the drawings.

Embodiments of the present invention provide an apparatus for electromagnetic compatibility (EMC) shielding of gaps surrounding interconnects on a system chassis. Connectors on information technology (IT) equipment often include a gap between a connector housing and an edge of the system chassis that allow for electromagnetic emissions to escape and/or enter the system chassis resulting in a disturbance to the environment and/or equipment. Though a size of the gap between the connector housing and the edge of the system chassis limit a frequency and power levels of the electromagnetic emissions, external orientated connector housings are common locations for emitted noise and sensitivity to disturbance. Furthermore, the system chassis typically includes multiple connector housings arranged in a stacked and/or linear manner, where the gap between the multiple connectors housings spans a substantial length of the system chassis resulting in a large gap for electromagnetic emissions to escape and/or enter the system chassis.

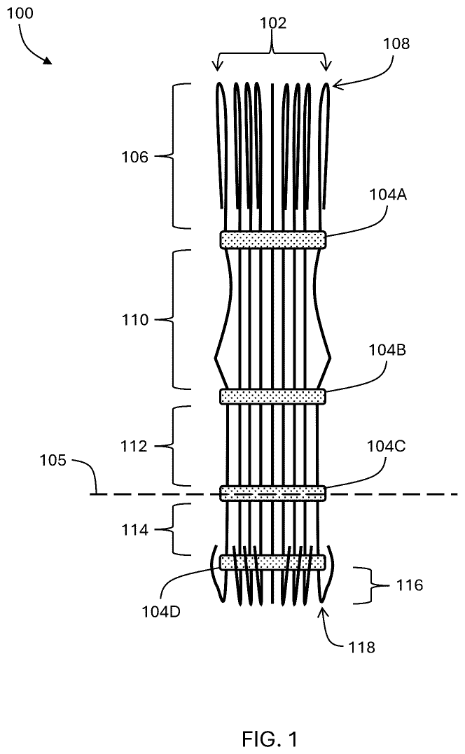

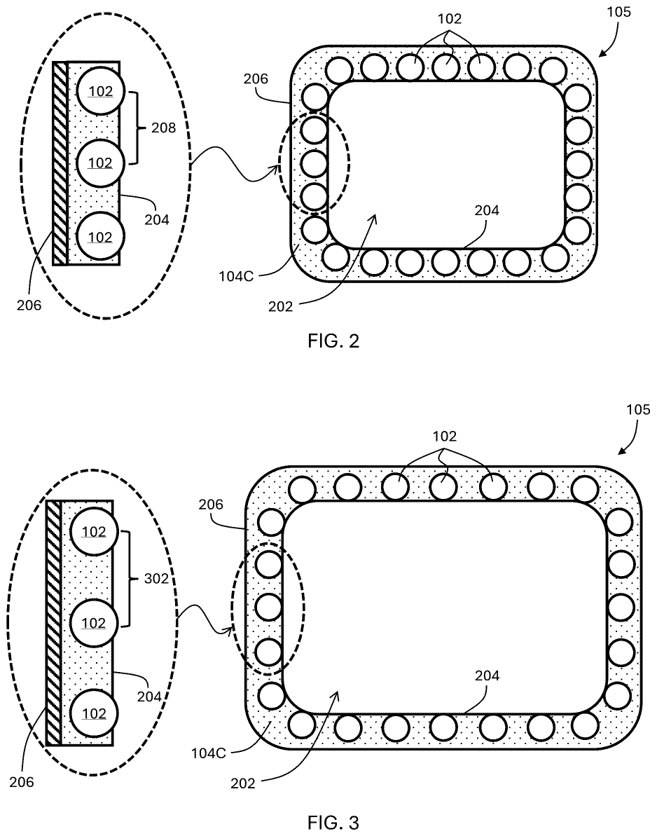

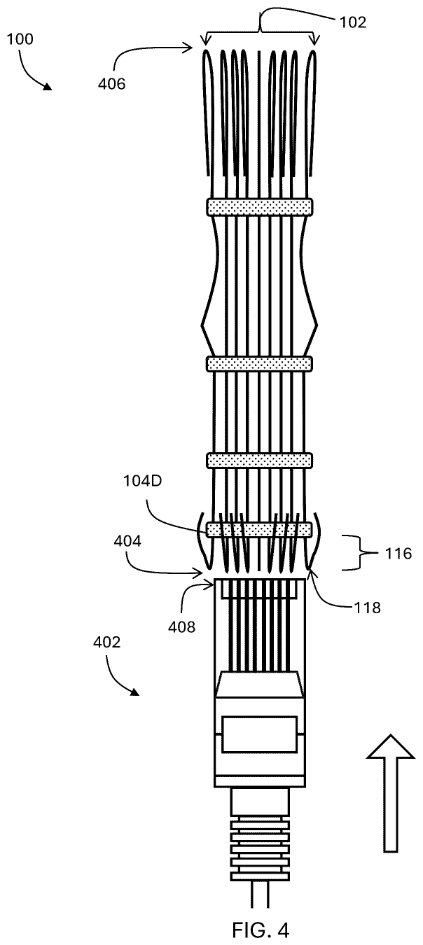

FIG. 1 depicts a top view of a conductive sheath for a cable connector to provide EMC shielding surrounding a connector housing, in accordance with an embodiment of the present invention. In this embodiment, conductive sheath 100 includes a plurality of conductive members 102 with multiple expandable bands 104A, 104B, 104C, and 104D. Each of the plurality of conductive members 102 are of a flexible, malleable, and conductive material such that, conductive sheath 100 conforms to a shape of a cable connector being inserted into conductive sheath 100. Dimensions and a number of a plurality of conductive members 102 varies depending on an application and EMC shielding requirements of conductive sheath 100. Expandable bands 104A, 104B, 104C, and 104D are of an elastic material that expands and contracts to allow for the plurality of conductive members 102 of conductive sheath 100 to conform to the cable connector. Each of the plurality of conductive members 102 are coupled to each of expandable bands 104A, 104B, 104C, and 104D of conductive sheath 100. Cross sectional view 105 of expandable band 104C in a contracted state and an expanded state are provided in FIGS. 2 and 3, respectively. Dimensions and elasticity of expandable bands 104A, 104B, 104C, and 104D varies depending on an application and EMC shielding requirements of conductive sheath 100.

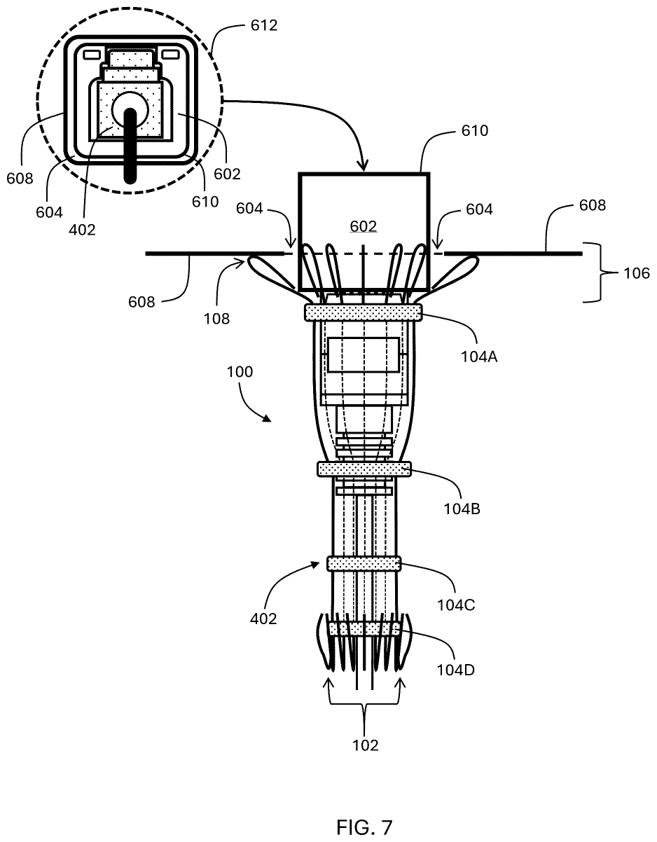

In this embodiment, conductive sheath 100 includes first section 106, where a first leading end of each of the plurality of conductive members 102 includes first radial bend 108 that defines a fold in each of the plurality of conductive members 102 in first section 106. First radial bend 108 in each of the plurality of conductive members 102 allows for first section 106 of conductive sheath 100 to conform to a surface where a connector housing is located. The conforming of first section 106 of conductive sheath 100 is discussed in further detail with regards to FIG. 7. A first length of first section 106 is defined by a first location of first radial bend 108 of each conductive member 102 and a second location where each conductive member 102 enters expandable band 104A.

Conductive sheath 100 includes second section 110 located between expandable band 104A and 104B. A second length of second section 110 is defined by a first location where each conductive member 102 exits expandable band 104A and a second location where each conductive member 102 enters expandable band 104B. A shape of each portion of conductive member 102 located in second section 110 is dependent on an amount of conforming that occurs when a cable connector is inserted into conductive sheath 100. Conductive sheath 100 includes third section 112 located between expandable band 104B and 104C. A third length of third section 112 is defined by a first location where each conductive member 102 exits expandable band 104B and a second location where each conductive member 102 enters expandable band 104C. Conductive sheath 100 includes fourth section 114 located between expandable band 104C and 104D. A fourth length of fourth section 114 is defined by a first location where each conductive member 102 exits expandable band 104C and a second location where each conductive member 102 enters expandable band 104D.

Conductive sheath 100 includes fifth section 116, where a second leading end of each of the plurality of conductive members 102 includes second radial bend 118 that defines a fold in each of the plurality of conductive members 102 in fifth section 116. Second radial bend 118 of each conductive member 102 guides the cable connector into conductive sheath 100 when the cable connector is being inserted into conductive sheath 100. A fifth length of fifth section 116 is defined by a first location of second radial bend 118 of each conductive member 102 and a second location where each conductive member 102 exits expandable band 104D.

FIG. 2 depicts a cross-sectional view of an elastic band of a conductive sheath for a cable connector, in accordance with an embodiment of the present invention. In this embodiment, cross sectional view 105 is of expandable band 104C in a contracted state, where a plurality of conductive members 102 are positioned around a perimeter of aperture 202 of expandable band 104C between inner wall 204 and outer wall 206. An area of aperture 202 of expandable band 104C is defined by inner wall 204 as expandable band 104C expands and contracts when conforming to a cable connector. A portion of each conductive members 102 can extend beyond a planar surface of inner wall 204 to guide the cable connector through aperture 202 of expandable band 104C. As previously discussed, expandable band 104C is of an elastic material that expands and contracts to allows for the plurality of conductive members 102 to conform to the cable connector. Contracted distance 208 illustrates a distance between two of the plurality of conductive members 102 in the contract state.

In this embodiment, the plurality of conductive members 102 are positioned in a single row around the perimeter of aperture 202 of expandable band 104C between inner wall 204 and outer wall 206. Each conductive member 102 is coupled to a medium of elastic material positioned between inner wall 204 and outer wall 206 of expandable band 104C. In another embodiment the plurality of conductive members 102 are positioned in a single row, where each conductive member 102 is offset when compared to a position of an adjacent (i.e., neighboring) conductive member 102. In yet another embodiment, multiple rows of conductive member 102 are positioned around the perimeter of aperture 202 of expandable band 104C between inner wall 204 and outer wall 206. It is to be noted that a shape of aperture 202 of expandable band 104C can vary between applications depending on a shape of the cable connector and EMC shielding requirements. It is to be noted, that expandable band 104C is also an illustrative cross sectional view of expandable band 104A, 104B, and 104D.

FIG. 3 depicts a cross-sectional view of an elastic band of a conductive sheath for a cable connector in an expanded state, in accordance with an embodiment of the present invention. In this embodiment, cross sectional view 105 is of expandable band 104C in an expanded state, where expanded distance 302 illustrates a distance between two of the plurality of conductive members 102 in the expanded state. Expanded distance 302 of the expanded state is greater than contracted distance 208 of the contracted state illustrated in FIG. 2. In the expanded state, a perimeter of inner wall 204 and outer wall 206 of expandable band 104C increases, resulting in an increased area of aperture 202 and an increased distance between conductive members 102 (i.e., expanded distance 302). Since the distance increases between conductive members 102 in the expanded state, an amount and orientation of conductive members 102 in expandable band 104C is taken into consideration to ensure optimal EMC shielding.

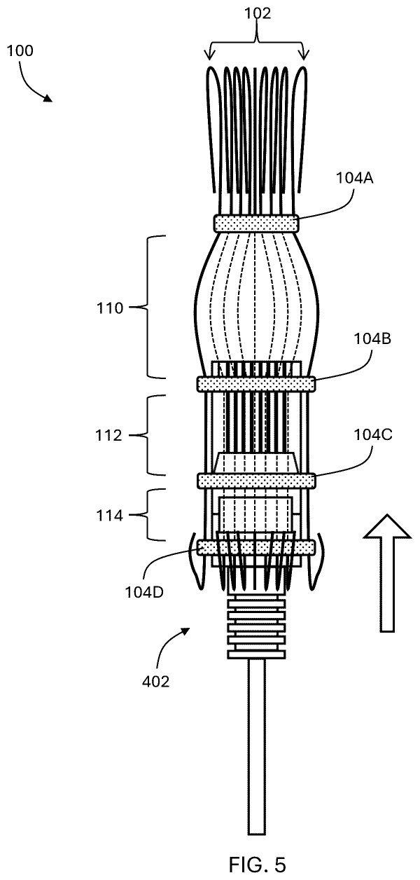

FIG. 4 depicts a top view of a conductive sheath prior to insertion of a cable connector to provide EMC shielding surrounding a connector housing, in accordance with an embodiment of the present invention. In this embodiment, cable connector 402 is positioned near the second leading end of each of the plurality of conductive members 102 that includes second radial bend 118 that defines a fold in each of the plurality of conductive members 102 in fifth section 116. Cable connector 402 is insertable at first end 404 of conductive sheath 100, where second end 406 of conductive sheath 100 is located opposite first end 404. Second radial bend 118 of each conductive member 102 guides leading edge 408 of cable connector 402 into conductive sheath 100 when the cable connector is being inserted into conductive sheath 100. A shape and dimensions of each conductive member 102 can vary depending on an application of conductive sheath 100 and a shape and dimensions of cable connector 402. As leading edge 408 of cable connector 402 contacts second radial bend 118 of each conductive member 102, the second leading end of each of the plurality of conductive members 102 expand outward to accept the leading edge of cable connector 402. As the plurality of conductive members 102 expand outward, the movement results in expandable band 104D transitions from a contracted state to an expanded state.

FIG. 5 depicts a top view of a conductive sheath with a partially inserted cable connector to provide EMC shielding surrounding a connector housing, in accordance with an embodiment of the present invention. In this embodiment, cable connector 402 is partially inserted into conductive sheath 100. Since a perimeter of cable connector 402 is greater than a perimeter of an aperture of expandable band 104B, 104C, and 104D, each of expandable band 104B, 104C, and 104D expand to conform to the perimeter (i.e., shape) of cable connector 402. As previously discussed, conductive members 102 are of a flexible, malleable, and conductive material, allowing for each conductive member 102 to change shape as each of expandable band 104B, 104C, and 104D expands and contracts during the insertion of cable connector 402 into conductive sheath 100. The insertion of cable connector 402 through fourth section 114, third section 112, and second section 110 of conductive sheath 100 results in expandable band 104B, 104C, and 104D transitioning from a contracted state to an expanded state. The transition from the contracted state to the expanded state results in a deformation of conductive members 102.

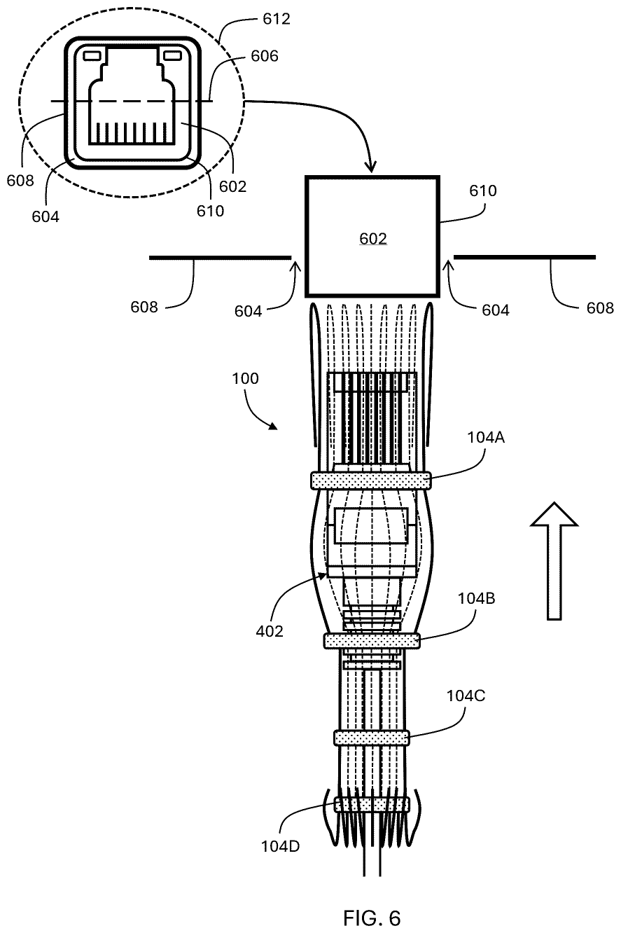

FIG. 6 depicts a top view of a conductive sheath with an inserted cable connector prior to insertion into a connector housing, in accordance with an embodiment of the present invention. In this embodiment, cable connector 402 is inserted into conductive sheath 100 prior to cable connector 402 being inserted into connector housing 602. Cable connector 402 is disposed in an aperture (e.g., aperture 202 of expandable band 104C) of each of expandable band 104A, 104B, 104C, and 104D. Each of expandable band 104A, 104B, 104C, and 104D conforms to a different portion of cable connector 402. For example, expandable band 104A (i.e., first expandable band) can conform to a first shape of a first portion of cable connector 402 and expandable band 104B (i.e., second expandable band) can conform to a second shape of a second portion of cable connector 402.

Connector housing 602 is a receptacle for inserting cable connector 402 with conductive sheath 100, where conductive sheath 100 provides EMC shielding for gap 604 that is present around a perimeter of connector housing 602. Gap 604 presents an area through which electromagnetic emissions can escape and/or enter a system chassis housing various IT equipment. Though in this embodiment, gap 604 is present around the perimeter of connector housing 602, gap 604 can exist on a minimum of one side of connector housing 602 for conductive sheath 100 to provide the benefits of EMC shielding. In the top view, cross section 606 of connector housing 602 is shown to illustrate gap 604 between wall 608 of the system chassis and enclosure 610 of connector housing 602. Front view 612 of connector housing 602 further illustrates a location of cross section 606 of connector housing 602. It is to be noted that embodiments discussed herein are not only applicable to system chassis, but to any device and/or system that includes gap 604 surrounding connector housing 602.

FIG. 7 depicts a top view of a conductive sheath with an inserted cable connector inserted into a connector housing to provide EMC shielding surrounding the connector housing, in accordance with an embodiment of the present invention. In this embodiment, cable connector 402 with conductive sheath 100 is disposed in connector housing 602, where a plurality of conductive members 102 of conductive sheath 100 provide EMC shielding to cover gap 604. It is to be noted, at least one of the plurality of conductive members 102 can cover gap 604. As previously discussed, conductive sheath 100 includes first section 106, where a first leading end of each of the plurality of conductive members 102 includes first radial bend 108 that defines a fold in each of the plurality of conductive members 102 in first section 106. First radial bend 108 in each of the plurality of conductive members 102 allows for first section 106 of conductive sheath 100 to conform to a surface where connector housing 602 is positioned. Upon insertion of cable connector 402 into connector housing 602, conductive sheath 100 is pushed forward and first radial bend 108 of each conductive member 102 contacts enclosure 610 of connector housing 602. First radial bend 108 of each conductive member 102 contacting enclosure 610 of connector housing 602 results in conductive members 102 of first section 106 to flare out and cover gap 604 that surrounds a perimeter of connector housing 602. Conductive sheath 100 can further include a ground bound to any of expandable band 104A, 104B, 104C, and 104D to eliminate any extraneous noise.

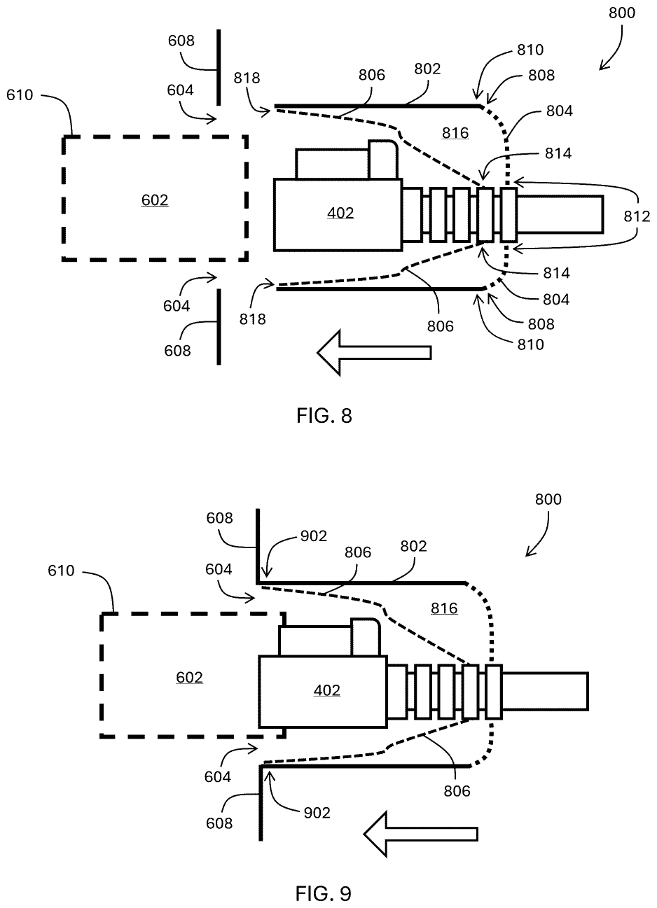

FIG. 8 depicts a side view of a cable connector with a deployable sheath prior to insertion into a connector housing, in accordance with an embodiment of the present invention. In this embodiment, deployable sheath 800 includes fixed case 802, a plurality of flexible members 804, and conductive members 806. A cross sectional view of cable connector 402, connector housing 602, and deployable sheath 800 illustrates an insertion and deployment of conductive members 806 into a system chassis. As previously noted, embodiments discussed herein are not only applicable to system chassis, but to any device and/or system that includes gap 604 surrounding connector housing 602. Fixed case 802 surrounds cable connector 402, where first end 808 of each of the plurality of flexible members 804 is coupled to first end 810 of fixed case 802. Second end 812 of each of the plurality of flexible members 804 is coupled to an area on cable connector 402, where the plurality of flexible members 804 are configured to allow for a movement of fixed case 802. In this embodiment, the movement of fixed case 802 is parallel to an insertion direction of cable connector 402 into connector housing 602.

Each of a plurality of conductive members 806 are of a flexible, malleable, and conductive material. First end 814 of each conductive member 806 is coupled to an area of cable connector 402, where conductive members 806 are disposed within void 816 defined by fixed case 802 and the plurality of flexible members 804. Cable connector 402 is also disposed in void 816 in a retracted state, prior to insertion into connector housing 602. Second end 818 of each conductive member 806 is pressed against an inner surface of fixed case 802 until there is movement of fixed case 802 due to the insertion of cable connector 402 into connector housing 602. Dimensions and a number of a plurality of conductive members 806 varies depending on an application and EMC shielding requirements of deployable sheath 800.

Gap 604 surrounds a perimeter of enclosure 610 of connector housing 602, between wall 608 of the system chassis and enclosure 610. In this embodiment, conductive members 806 of deployable sheath 800 provide EMC shielding by extending (i.e., deploying) conductive members 806 into gap 604 beyond a planar surface of wall 608 of the system chassis. Each conductive member 806 is spring loaded in a manner to allow for each conductive member 806 to flare out once the planar surface of wall 608 of the system chassis is crossed.

FIG. 9 depicts a side view of a cable connector with a deployable sheath partially inserted into a connector housing, in accordance with an embodiment of the present invention. In this embodiment, cable connector 402 is partially inserted into connector housing 602, where lead edge 902 (i.e., second end) of fixed case 802 of deployable sheath 800 contacts wall 608 of a system chassis. Dimensions of void 816 of deployable sheath 800 are such that wall 608 prevents fixed case 802 from crossing a planar surface of wall 608 of the system chassis, while allowing for each conductive member 806 to cross the planar surface of wall 608 of the chassis. Each conductive member 806 crosses the planar surface of wall 608 through gap 604 located between enclosure 610 of connector housing 602 and wall 608 of the system chassis.

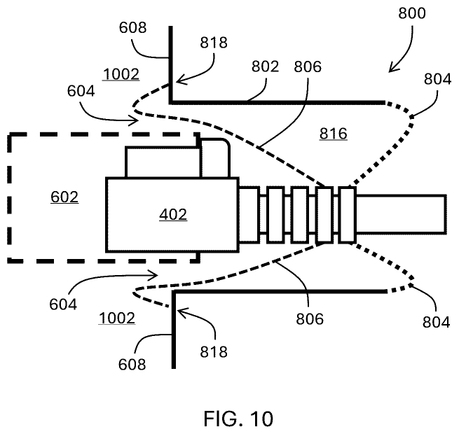

FIG. 10 depicts a side view of a cable connector with a deployable sheath inserted into a connector housing, in accordance with an embodiment of the present invention. In this embodiment, cable connector 402 is inserted into connector housing 602 with conductive members 806 deployed to provide EMC shielding. Due to the dimension of void 816 of deployable sheath 800, wall 608 of a system chassis prevents a movement of fixed case 802 upon insertion of cable connector 402 into connector housing 602. As fixed case 802 is pressed against wall 608 of the system chassis, the plurality of flexible members 804 bend to allow the movement of cable connector 402 and subsequent docking of cable connector 402 with connector housing 602. Since conductive members 806 are spring loaded, each conductive member 806 flares out into system chassis void 1002 and second end 818 of each conductive member 806 is pressed against an inner surface of wall 608 covering gap 604. It is to be noted, at least one of the plurality of conductive members 806 can cover gap 604.

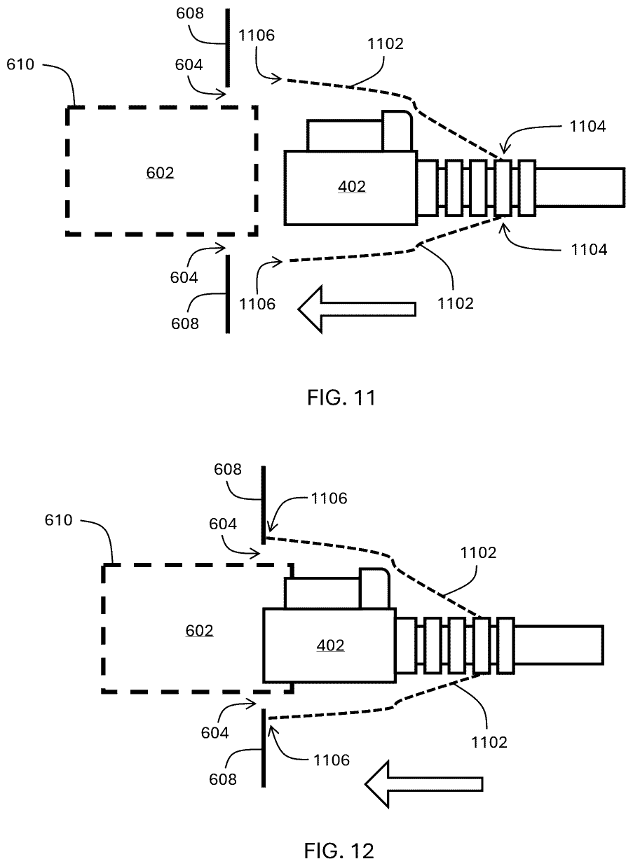

FIG. 11 depicts a side view of a cable connector with conductive members prior to insertion into a connector housing, in accordance with an embodiment of the present invention. In this embodiment, cable connector 402 includes a plurality of conductive members 1102 for providing EMC shielding. A cross sectional view of cable connector 402 with conductive members 1102 and connector housing 602 illustrates an insertion and deployment of conductive members 1102 external to a system chassis. As previously noted, embodiments discussed herein are not only applicable to system chassis, but to any device and/or system that includes gap 604 surrounding connector housing 602. Each of a plurality of conductive members 1102 are of a flexible, malleable, and conductive material. First end 1104 of each conductive member 1102 is coupled to an area of cable connector 402, where second end 1106 of each conductive members 1102 is positioned to contact wall 608 of the system chassis upon insertion of cable connector 402 into connector housing 602. Dimensions and a number of a plurality of conductive members 1102 varies depending on an application and EMC shielding requirements.

Gap 604 surrounds a perimeter of enclosure 610 of connector housing 602, between wall 608 of the system chassis and enclosure 610. In this embodiment, conductive members 1102 provide EMC shielding by flaring out against a planar surface of wall 608 external to the system chassis. Each of conductive members 1102 flares out in a manner to cover a portion of gap 604 surrounding enclosure 610 of connector housing 602, thus providing EMC shielding for gap 604. It is to be noted, at least one of the plurality of conductive members 1102 can cover gap 604. Each conductive of members 1102 is spring loaded in a manner to allow for each of conductive members 1102 to flare out subsequent to, second end 1106 of each conductive member 1102 contacts the planar surface of wall 608 of the system chassis.

FIG. 12 depicts a side view of a cable connector with conductive members partially inserted into a connector housing, in accordance with an embodiment of the present invention. In this embodiment, cable connector 402 is partially inserted into connector housing 602, where second end 1106 of each conductive member 1102 contacts wall 608 of a system chassis. A spacing between second end 1106 of each conductive member 1102 is such that each second end 1106 contacts wall 608. Therefore, a distance between second end 1106 of a first conductive member 1102 and second end 1106 of a second conductive member 1102 opposite first conductive member 1102, is greater than a combined distance of gap 604 and a height of connector housing 602.

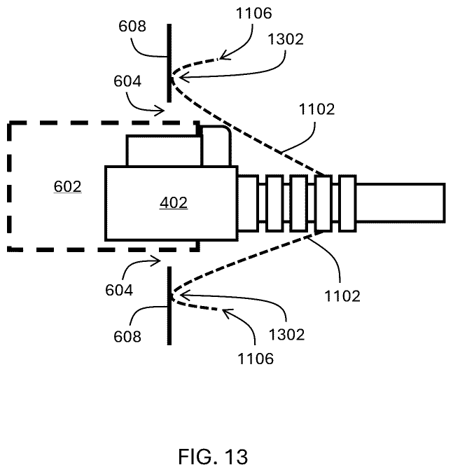

FIG. 13 depicts a side view of a cable connector with conductive members inserted into a connector housing, in accordance with an embodiment of the present invention. In this embodiment, cable connector 402 is disposed in connector housing 602 with conductive members 1102 externally deployed to provide EMC shielding. Since conductive members 1102 are spring loaded, each conductive member 1102 flares out upon second end 1106 of each conductive member 1102 contacting the planar surface of wall 608 of the system chassis. An initial shape of each conductive member 1102 is such that when second end 1106 of each conductive member 1102 contacts wall 608, radial bend 1302 is created in each conductive member 1102 representing the flared out final shape of conductive members 1102.

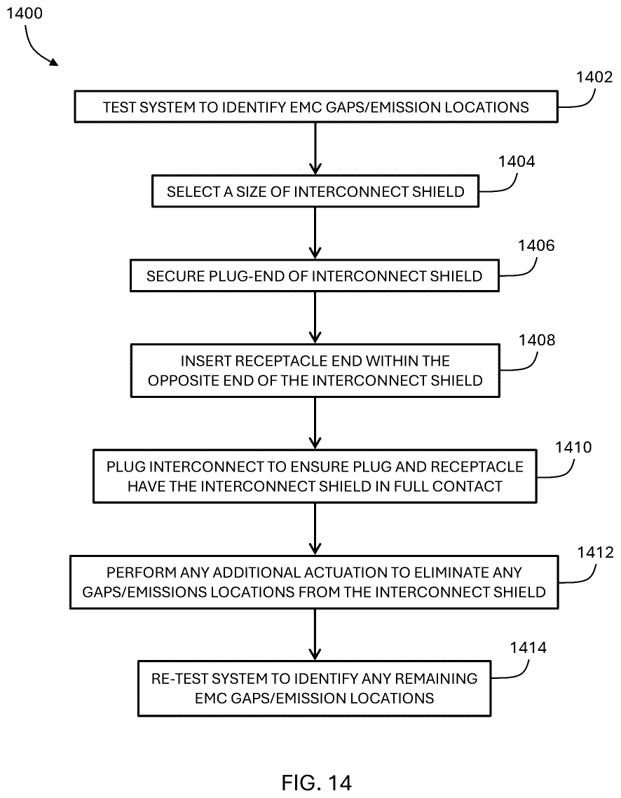

FIG. 14 depicts a process flow selecting and deploying an EMC shield for a connector housing, in accordance with an embodiment of the present invention. Process flow 1400 includes selecting and deploying an EMC shield (i.e., interconnect shield) for a connector housing, such as, conductive sheath 100 from FIG. 1, deployable sheath 800 from FIG. 8, and cable connector 402 with conductive members 1102 from FIG. 11. Process flow 1400 includes test a system to identify EMC gaps and emission locations (1402), selecting a size of an interconnect shield (1404), securing a plug-end of interconnect shield (1406), inserting a receptacle end (i.e., connector housing) within the opposite end of the interconnect shield (1408), plugging the interconnect to ensure the plug (i.e., connector end) and receptacle have the interconnect shield in full contact (1410), performing any additional actuation to eliminate any gaps and emission locations from the interconnect shield (1412), and re-testing the system to identify any remaining EMC gaps and emission locations (1414).

The terminology used herein is for the purpose of describing particular embodiments only and is not intended to be limiting to the invention. As used herein, the singular forms “a”, “an” and “the” are intended to include the plural forms as well, unless the context clearly indicates otherwise.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. An apparatus comprising:
a plurality of conductive members and a first expandable band of a conductive sheath, wherein the plurality of conductive members are coupled to the first expandable band; and
a cable connector disposed in an aperture of the first expandable band of the conductive sheath, wherein the plurality of conductive members surround the cable connector along a perimeter of the first expandable band.

2. The apparatus of claim 1, wherein the cable connector is insertable at a first end of the conductive sheath.

3. The apparatus of claim 2, further comprising:
the cable connector is disposed in a connector housing, wherein at least one of the plurality of conductive members at a second end of the conductive sheath covers a gap between an enclosure of the connector housing and a wall.

4. The apparatus of claim 3, wherein the plurality of conductive members at the second end of the conductive sheath cover the gap between the enclosure of the connector housing and the wall.

5. The apparatus of claim 3, wherein the plurality of conductive members are of a flexible, malleable, and conductive material.

6. The apparatus of claim 4, further comprising:
a first section at the second end of the conductive sheath having a first radial bend in each of the plurality of conductive members.

7. The apparatus of claim 5, further comprising:
a second section at the first end of the conductive sheath having a second radial bend in each of the plurality of conductive members.

8. The apparatus of claim 6, wherein the first expandable band of the conductive sheath conforms to a shape of the cable connector.

9. The apparatus of claim 1, further comprising:
a second expandable band of the conductive sheath, wherein the plurality of conductive members are coupled to the second expandable band; and
the cable connector disposed in an aperture of the second expandable band of the conductive sheath, wherein the plurality of conductive members surround the cable connector along a perimeter of the second expandable band.

10. The apparatus of claim 9, wherein the first expandable band of the conductive sheath conforms to a first shape of a first portion of the cable connector and the second expandable band of the conductive sheath conforms to a second shape of a second portion of the cable connector.

11. An apparatus comprising:
a fixed case, a plurality of flexible members, and a plurality of conductive members of a deployable sheath, wherein the plurality of flexible members are coupled to the fixed case; and
a cable connector disposed in a void defined by the fixed case and the plurality of flexible members, wherein the plurality of conductive members are coupled to and surround the cable connector.

12. The apparatus of claim 11, further comprising:
the cable connector is disposed in a connector housing, wherein at least one of the plurality of conductive members extends beyond a planar surface of a wall into a void and covers a gap between an enclosure of the connector housing and the wall.

13. The apparatus of claim 12, wherein the plurality of conductive members extend beyond the planar surface of the wall into the void and cover the gap between the enclosure of the connector housing and the wall.

14. The apparatus of claim 13, wherein the plurality of conductive members are of a flexible, malleable, and conductive material.

15. The apparatus of claim 14, wherein the plurality of flexible members allow for a movement of the fixed case in parallel to an insertion direction of the cable connector into the connector housing.

16. An apparatus comprising:
a plurality of conductive members coupled to a cable connector disposed in a connector housing, wherein at least one of the plurality of conductive members is flared out against a wall and covers a gap between an enclosure of the connector housing and the wall.

17. The apparatus of claim 16, wherein the plurality of conductive members are flared out against the wall and cover the gap between the enclosure of the connector housing and the wall.

18. The apparatus of claim 17, wherein the plurality of conductive members are of a flexible, malleable, and conductive material.

19. The apparatus of claim 18, wherein a first end of each of the plurality of conductive members is coupled to the cable connector.

20. The apparatus of claim 17, wherein the plurality of conductive members surround a perimeter of the cable connector.
